(19) United States
(12) Patent Application Publication
(10) Pub. No.: US 2018/0217343 A1
(43) Pub. Date: Aug. 2, 2018

(54) OPTICAL MODULE

(71) Applicant: FUJITSU LIMITED, Kawasaki-shi (JP)

(72) Inventors: Takayoshi Matsumura, Yokohama (JP); Naoaki Nakamura, Kawasaki (JP); NORIO KAINUMA, Nagano (JP); KENJI FUKUZONO, Kawasaki (JP); Yuki Hoshino, Yokohama (JP); TAKASHI KUBOTA, Chikuma (JP); Takumi Masuyama, Kawasaki (JP); Hidehiko Kira, Nagano (JP)

(73) Assignee: FUJITSU LIMITED, Kawasaki-shi (JP)

(21) Appl. No.: 15/874,927

(22) Filed: Jan. 19, 2018

(30) Foreign Application Priority Data
Jan. 27, 2017 (JP) 2017-013242

(51) Int. Cl. G02B 6/42; H01S 5/022; H01S 5/024

(52) U.S. Cl. CPC G02B 6/4269; G02B 6/4257; G02B 6/428; H01S 5/02276; H01L 23/367; H01S 5/02438; H01S 5/02469; H01S 5/0226; H01S 5/02208; H01S 5/02248

(57) ABSTRACT

An optical module includes a housing; a substrate configured to have a through hole; a first chip configured to have a first heating member and be disposed inside the through hole; a second chip configured to have a second heating member, the second chip being placed on the substrate and the first chip with a bump interposed; a first heat conduction member configured to be sandwiched between a lower wall of the housing and the first chip and transfer heat generated by the first heating member to the lower wall of the housing; and a second heat conduction member configured to be sandwiched between an upper wall of the housing and the second chip and transfer heat generated by the second heating member to the upper wall of the housing.

### CROSS-REFERENCE TO RELATED APPLICATION

This application is based upon and claims the benefit of priority of the prior Japanese Patent Application No. 2017-013242, filed on Jan. 27, 2017, the entire contents of which are incorporated herein by reference.

### FIELD

The embodiments discussed herein are related to an optical module.

### BACKGROUND

As regards an optical module on which a silicon photonics (Si-Ph) chip and a control chip are mounted, shortening of wiring and high-efficiency cooling are requested along with an increase in communication speed. FIGS. 21A and 21B and FIGS. 22A and 22B illustrate a using example of an optical module 101 of the Quad Small Form-Factor Pluggable (QSFP) standard. As illustrated in FIGS. 21A and 21B, the optical module 101 is inserted into a cage 102 which is attached to a server or the like. A cable 104 is connected to a housing 103 of the optical module 101 and heat radiation fins 105 are provided on a surface of the cage 102. FIGS. 21A and 22A illustrate a state before the optical module 101 is inserted into the cage 102, while FIGS. 218 and 22B illustrate a state after the optical module 101 is inserted into the cage 102.

Japanese Laid-open Patent Publication No. 2004-179309, International Publication Pamphlet No. WO 2007/114384, Japanese Laid-open Patent Publication No. 2006-261311, and Japanese Laid-open Patent Publication No. 7-58257 are examples of related art.

FIG. 23 is a sectional view illustrating the optical module 101. FIG. 23 illustrates a state in which the optical module 101 is inserted in the cage 102. A lower wall 103A of the housing 103 is in contact with a lower wall 102A of the cage 102 and an upper wall 103B of the housing 103 is in contact with an upper wall 102B of the cage 102. The optical module 101 includes a substrate 106, a Si-Ph chip 110, and a control chip 120. The Si-Ph chip 110 and the control chip 120 are provided on the substrate 106. A laser diode 111 and fins 112 are mounted on the Si-Ph chip 110 and heat of the laser diode 111 is radiated by the fins 112. Fins 121 are mounted on the control chip 120 and heat of a circuit of the control chip 120 is radiated by the fins 121. The Si-Ph chip 110 and the control chip 120 are electrically connected to each other via a wire 130.

Calorific values of the laser diode 111 and the circuit of the control chip 120 are large. Even in the case where the calorific values of the laser diode 111 and the circuit of the control chip 120 are large, it is possible to cool down the laser diode 111 by the fins 112 and cool down the circuit of the control chip 120 by the fins 121 because the distance between the laser diode 111 and the circuit of the control chip 120 is large. However, in the case where the distance between the Si-Ph chip 110 and the control chip 120 is large, a communication speed between the Si-Ph chip 110 and the control chip 120 decreases, causing a difficulty in dealing with an increase in communication speed. On the other hand, in the case where the distance between the Si-Ph chip 110 and the control chip 120 is shortened to improve the communication speed, the distance between the laser diode 111 and the circuit of the control chip 120 becomes short. In this case, there is a possibility that the temperature of the optical module 101 locally becomes high and results in insufficient cooling of the laser diode 111 and the circuit of the control chip 120.

### SUMMARY

According to an aspect of the embodiments, an optical module includes a housing; a substrate configured to have a through hole; a first chip configured to have a first heating member and be disposed inside the through hole; a second chip configured to have a second heating member, the second chip being placed on the substrate and the first chip with a bump interposed; a first heat conduction member configured to be sandwiched between a lower wall of the housing and the first chip and transfer heat generated by the first heating member to the lower wall of the housing; and a second heat conduction member configured to be sandwiched between an upper wall of the housing and the second chip and transfer heat generated by the second heating member to the upper wall of the housing.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a lateral view illustrating an optical module according to a first embodiment and FIG. 1B is a sectional view illustrating a cage according to the first embodiment;

FIG. 2 is a schematic view illustrating a state in which the optical module is inserted in the cage;

FIG. 3 is a sectional view illustrating the optical module according to the first embodiment;

FIG. 4 is a plan view illustrating the optical module according to the first embodiment;

FIG. 5 is a bottom view illustrating a wiring board and a heat sink;

FIG. 6 is a bottom view illustrating the wiring board and a heat sink;

FIG. 7 is a sectional view illustrating an optical module according to the first embodiment;

FIG. 8 is a sectional view illustrating an optical module according to a modification of the first embodiment;

FIG. 9 is a sectional view illustrating an optical module according to a modification of the first embodiment;

FIG. 10 is a sectional view illustrating an optical module according to a second embodiment;

FIG. 11 is a sectional view Illustrating an optical module according to a modification of the second embodiment;

FIG. 12 is a sectional view illustrating an optical module according to a third embodiment;

FIG. 13 is a sectional view illustrating an optical module according to a fourth embodiment;

FIG. 14 is a plan view illustrating the optical module according to the fourth embodiment;

FIG. 15 is a sectional view illustrating an optical module according to a fifth embodiment;

FIG. 16 is a plan view illustrating the optical module according to the fifth embodiment;

FIG. 17 is a sectional view illustrating a wiring board;

FIG. 18 is a sectional view illustrating an optical module according to a sixth embodiment;

FIG. 19 is a plan view illustrating the optical module according to the sixth embodiment;

FIG. 20 is a sectional view illustrating an optical module according to a reference example;

FIGS. 21A and 21B illustrate a using example of an optical module of the QSFP type;

FIGS. 22A and 22B illustrate a using example of the optical module of the QSFP type; and

FIG. 23 is a sectional view illustrating an optical module.

### DESCRIPTION OF EMBODIMENTS

Embodiments will be described in detail below with reference to the accompanying drawings. The configuration of each of the following embodiments is an example and the present disclosure is not limited to the configuration of each embodiment.

### First Embodiment

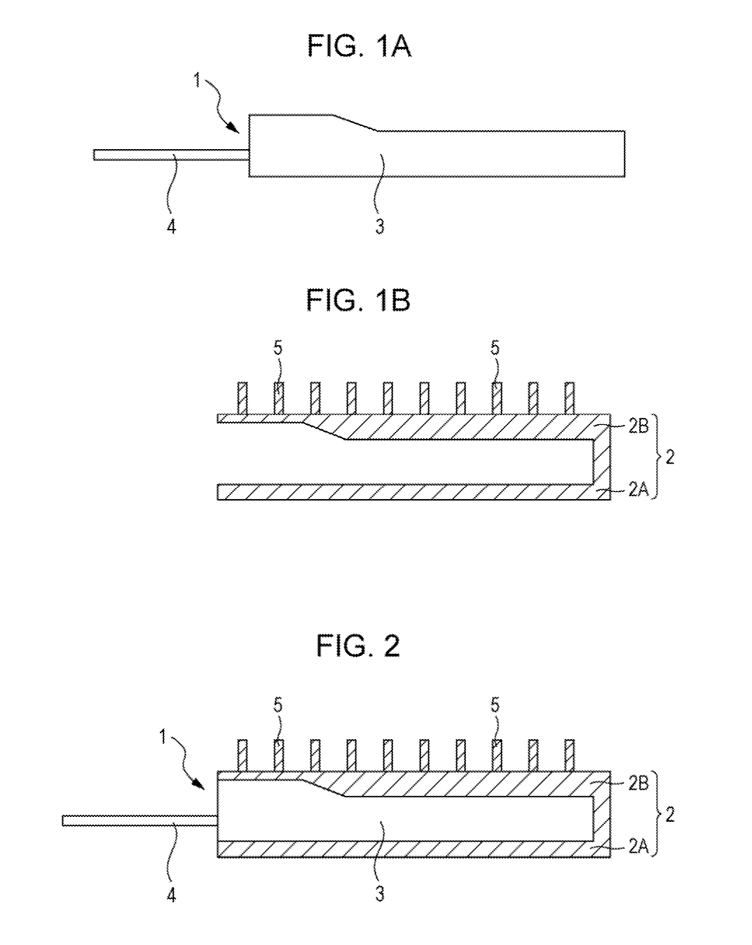

The first embodiment will be described. FIG. 1A is a lateral view Illustrating an optical module 1 according to the first embodiment and FIG. 1B is a sectional view illustrating a cage 2 according to the first embodiment. FIG. 2 is a schematic view illustrating a state in which the optical module 1 is inserted in the cage 2. The optical module 1 is, for example, an optical connector of the QSFP standard, but the optical module 1 may be an optical connector of another standard. The optical module 1 includes a housing 3 and a cable 4. A plurality of heat radiation fins 5 are provided on a surface of an upper wall 28 of the cage 2. The optical module 1 is detachably inserted into the cage 2. The cage 2 is attached to a server or the like, for example. The cage 2 detachably accommodates the optical module 1. The cage 2 is a box-shaped member having an insertion opening into which the optical module 1 is inserted. A connector is provided in the cage 2. When the optical module 1 is inserted into the cage 2, the optical module 1 is electrically and mechanically connected to the connector in the cage 2. Thus, an electrical signal is transmitted between the optical module 1 and the server or the like. Heat of the optical module 1 is transferred to the cage 2 and is radiated by the heat radiation fins 5.

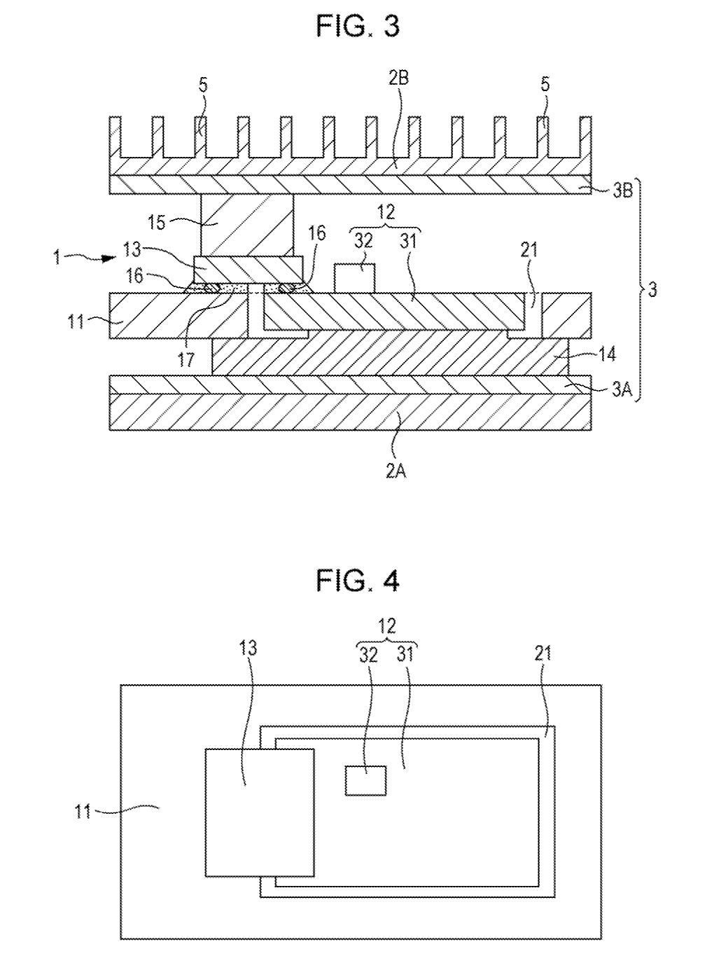

FIG. 3 is a sectional view illustrating the optical module 1 according to the first embodiment. FIG. 3 illustrates a state in which the optical module 1 is inserted in the cage 2. The housing 3 includes a lower wall 3A and an upper wall 3B. The lower wall 3A of the housing 3 is in contact with a lower wall 2A of the cage 2 and the upper wall 3B of the housing 3 is in contact with the upper wall 2B of the cage 2. The housing 3 is formed using a metal material such as copper (Cu) and aluminum (AI) or resin having thermal conductivity. The optical module 1 includes a wiring board 11, a silicon photonics (Si-Ph) chip 12, a control chip 13, and heat sinks 14 and 15. The wiring board 11 is an example of a substrate. The Si-Ph chip 12 is an example of a first chip. The control chip 13 is an example of a second chip.

The wiring board 11, the Si-Ph chip 12, the control chip 13, and the heat sinks 14 and 15 are disposed inside the housing 3. The wiring board 11 is disposed on the heat sink 14 provided on the lower wall 3A of the housing 3. For example, the heat sink 14 provided on the lower wall 3A of the housing 3 may be in contact with an outer peripheral portion of the lower surface of the wiring board 11. The upper wall 38 of the housing 3 is sometimes referred to as a ceiling. Here, it is assumed that even if the housing 3 is rotated by 90 degrees, the nominal designations of the lower wall 3A and the upper wall 3B remain unchanged. The Si-Ph chip 12 includes a silicon substrate 31 and a laser diode 32 which is provided on the silicon substrate 31. The laser diode 32 is provided on a surface on which the circuit of the Si-Ph chip 12 is formed (circuit surface). In addition, the Si-Ph chip 12 includes a photodiode which is provided on the silicon substrate 31.

The laser diode 32 and the photodiode are connected to the cable 4. The laser diode 32 converts an electrical signal inputted via the cable 4 into light. The photodiode converts light inputted via the cable 4 into an electrical signal. An optical transceiver in which the laser diode 32 and the photodiode are integrated may be provided on the silicon substrate 31. The control chip 13 controls driving of the Si-Ph chip 12.

FIG. 4 is a plan view illustrating the optical module 1 according to the first embodiment. In FIG. 4, illustration of the housing 3 and the heat sink 15 is omitted. The wiring board 11 has a through hole 21 which penetrates through the wiring board 11. The Si-Ph chip 12 is disposed inside the through hole 21 of the wiring board 11. The whole or a part of the Si-Ph chip 12 is inserted in the through hole 21 of the wiring board 11. In the configuration example of the optical module 1 illustrated in FIGS. 3 and 4, the whole of the Si-Ph chip 12 is inserted in the through hole 21 of the wiring board 11. As Illustrated in FIGS. 3 and 4, an inner circumferential surface of the through hole 21 of the wiring board 11 may be separated from lateral surfaces of the Si-Ph chip 12. In the case where the inner circumferential surface of the through hole 21 of the wiring board 11 is separated from the lateral surfaces of the Si-Ph chip 12, an influence of deformation of the wiring board 11, which is generated when an external force is applied to the optical module 1, is restrained from spreading to the Si-Ph chip 12. Further, the inner circumferential surface of the through hole 21 of the wiring board 11 and a part of the lateral surfaces of the Si-Ph chip 12 may be in contact with each other.

The circuit surface of the Si-Ph chip 12 and a surface on which the circuit of the control chip 13 is formed (circuit surface) face each other. Further, an upper surface of the wiring board 11 and the circuit surface of the control chip 13 face each other. A bump 16 is provided between the wiring board 11 and the control chip 13 and a bump 16 is provided between the Si-Ph chip 12 and the control chip 13. The bump 16 is a solder ball, for example. The control chip 13 is placed on the wiring board 11 and the Si-Ph chip 12 with the bumps 16 interposed. Thus, the control chip 13 is disposed in a manner to straddle the wiring board 11 and the Si-Ph chip 12. Further, an underfill 17 is provided between the wiring board 11 and the control chip 13 and an underfill 17 is provided between the Si-Ph chip 12 and the control chip 13. By providing the underfills 17, connection reliability between the wiring board 11 and the control chip 13 and connection reliability between the Si-Ph chip 12 and the control chip 13 are improved.

On the upper surface of the wiring board 11, the circuit surface of the Si-Ph chip 12, and the circuit surface of the control chip 13, electrodes (not Illustrated) are provided. The bump 16 provided between the wiring board 11 and the control chip 13 is bonded to the electrode provided on the upper surface of the wiring board 11 and the electrode provided on the circuit surface of the control chip 13. The bump 16 provided between the Si-Ph chip 12 and the control chip 13 is bonded to the electrode provided on the circuit surface of the Si-Ph chip 12 and the electrode provided on the circuit surface of the control chip 13. The control chip 13 is electrically connected to the wiring board 11 via the bump 16 and is electrically connected to the Si-Ph chip 12 via the bump 16. An electrical signal is transmitted and received between the wiring board 11 and the control chip 13 via the bump 16 provided between the wiring board 11 and the control chip 13. An electrical signal is transmitted and received between the Si-Ph chip 12 and the control chip 13 via the bump 16 provided between the Si-Ph chip 12 and the control chip 13.

The heat sink 14 is sandwiched between the lower wall 3A of the housing 3 and the Si-Ph chip 12. The heat sink 14 is in contact with an opposite surface of the circuit surface of the Si-Ph chip 12 (hereinafter, referred to as the back surface of the Si-Ph chip 12) and is in contact with the lower wall 3A of the housing 3. The heat sink 15 is sandwiched between the upper wall 3B of the housing 3 and the control chip 13. The heat sink 15 is in contact with an opposite surface of the circuit surface of the control chip 13 (hereinafter, referred to as the back surface of the control chip 13) and is in contact with the upper wall 38 of the housing 3. The heat sinks 14 and 15 are heat conduction members and are formed using a metal material such as copper and aluminum, for example. The heat sink 14 transfers heat generated by the laser diode 32 to the lower wall 3A of the housing 3. The heat sink 15 transfers heat generated by the circuit of the control chip 13 to the upper wall 3B of the housing 3. The heat sink 14 is an example of a first heat conduction member. The heat sink 15 is an example of a second heat conduction member. The laser diode 32 is an example of a first heating member. The circuit of the control chip 13 is an example of a second heating member.

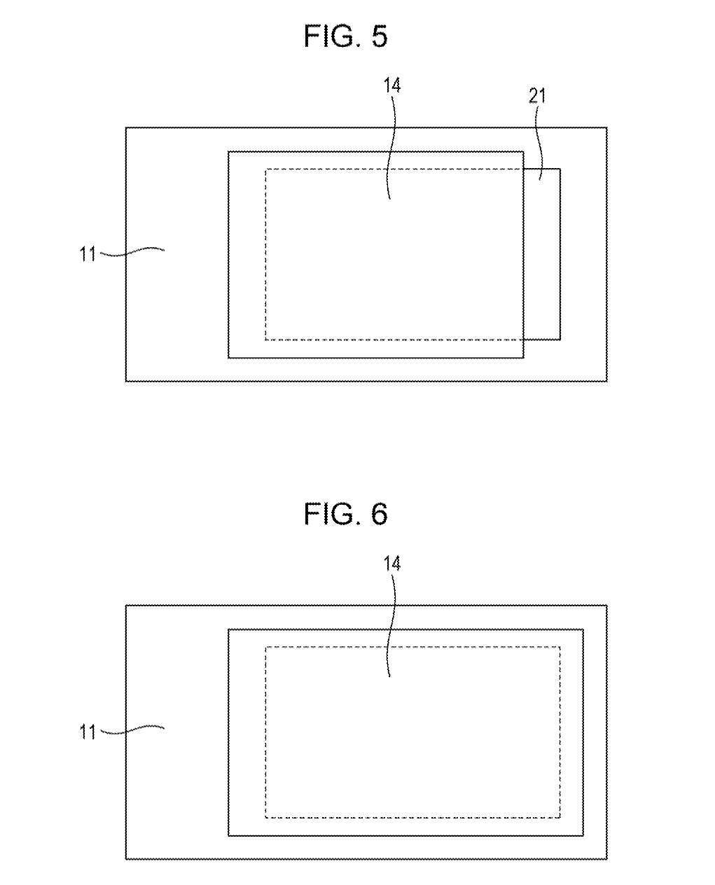

The heat sink 14 covers a part or the whole of the opening of the through hole 21 of the wiring board 11. In the configuration example of the optical module 1 illustrated in FIG. 3, the heat sink 14 covers the whole opening of the through hole 21 of the wiring board 11. A part of the heat sink 14 is sandwiched between the lower wall 3A of the housing 3 and the wiring board 11. The heat sink 14 is in contact with the lower surface of the wiring board 11 and in contact with the lower wall 3A of the housing 3. FIGS. 5 and 6 are bottom views illustrating the wiring board 11 and the heat sink 14. As illustrated in FIG. 5, the heat sink 14 may cover a part of the opening of the through hole 21 of the wiring board 11. As illustrated in FIG. 6, the heat sink 14 may cover the whole opening of the through hole 21 of the wiring board 11.

By disposing a part of the heat sink 14 between the wiring board 11 and the lower wall 3A of the housing 3, deformation of the wiring board 11 generated when an external force is applied to the optical module 1 is reduced. As a result, stress applied to a connection portion between the wiring board 11 and the control chip 13 is reduced and accordingly, connection reliability between the wiring board 11 and the control chip 13 is improved. In the configuration example of the optical module 1 illustrated in FIG. 3, since the thickness of the wiring board 11 is larger than the thickness of the silicon substrate 31, the heat sink 14 has a convex shape. A convex portion is formed in a central portion of an upper surface of the heat sink 14 and a top surface of the convex portion of the heat sink 14 is in contact with the back surface of the Si-Ph chip 12. Accordingly, a part of the heat sink 14 is inserted in the through hole 21 of the wiring board 11. The outer peripheral portion of the upper surface of the heat sink 14 is not in contact with the back surface of the Si-Ph chip 12. A part of the outer peripheral portion of the upper surface of the heat sink 14 is in contact with the lower surface of the wiring board 11.

In the case where the thickness of the wiring board 11 is larger than the thickness of the silicon substrate 31, the top surface of the convex portion of the heat sink 14 is brought into contact with the back surface of the Si-Ph chip 12, thereby being able to match or substantially match the level of the upper surface of the wiring board 11 and the level of the circuit surface of the Si-Ph chip 12 with each other. Thus, generation of a level difference between the upper surface of the wiring board 11 and the circuit surface of the Si-Ph chip 12 is suppressed and accordingly, the connection reliability between the wiring board 11 and the control chip 13 and the connection reliability between the Si-Ph chip 12 and the control chip 13 are improved. In the case where the thickness of the wiring board 11 and the thickness of the silicon substrate 31 are the same, the whole of the upper surface of the heat sink 14 may be formed to be flat.

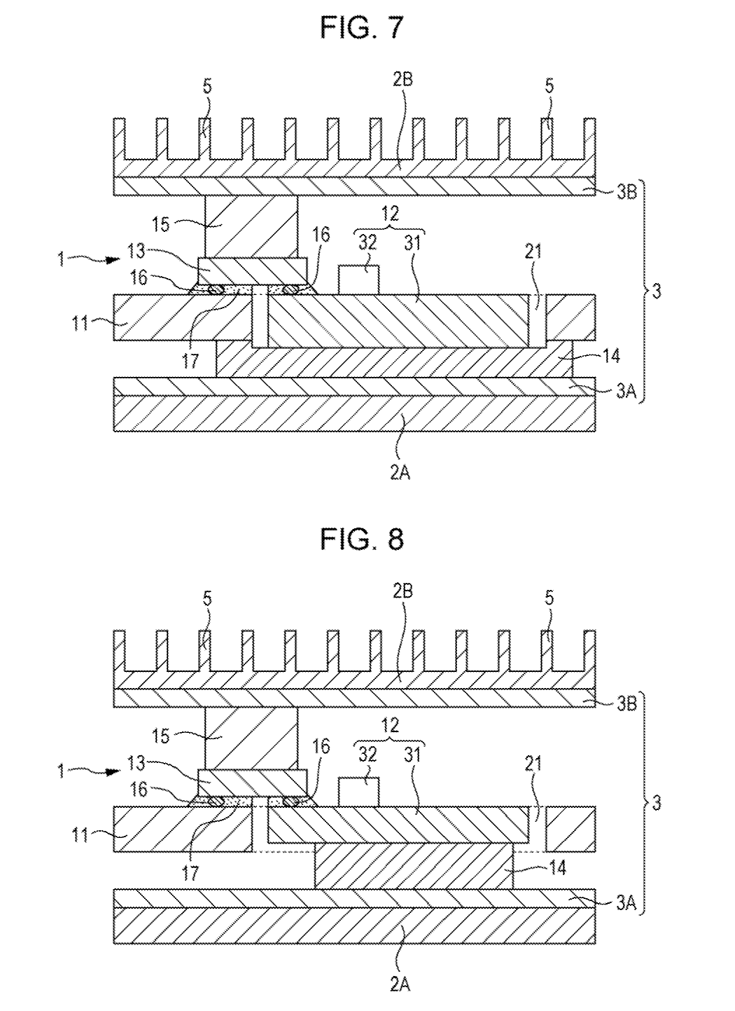

FIG. 7 is a sectional view illustrating the optical module 1 according to the first embodiment. As Illustrated in FIG. 7, the thickness of the wiring board 11 may be smaller than the thickness of the silicon substrate 31. In the configuration example of the optical module 1 illustrated in FIG. 7, a part of the Si-Ph chip 12 protrudes from the through hole 21 of the wiring board 11 and the heat sink 14 has a concave shape. A recess is provided in the central portion of the upper surface of the heat sink 14, and a part of the Si-Ph chip 12 is accommodated in the recess of the heat sink 14. The back surface of the Si-Ph chip 12 is in contact with a bottom surface of the recess of the heat sink 14. The outer peripheral portion of the upper surface of the heat sink 14 is not in contact with the back surface of the Si-Ph chip 12. The outer peripheral portion of the upper surface of the heat sink 14 is in contact with the lower surface of the wiring board 11. Therefore, the outer peripheral portion of the heat sink 14 is sandwiched between the lower wall 3A of the housing 3 and the wiring board 11.

In the case where the thickness of the wiring board 11 is smaller than the thickness of the silicon substrate 31, a part of the Si-Ph chip 12 is accommodated in the recess of the heat sink 14, thereby being able to match or substantially match the level of the top surface of the wiring board 11 and the level of the circuit surface of the Si-Ph chip 12 with each other. Thus, generation of a level difference between the upper surface of the wiring board 11 and the circuit surface of the Si-Ph chip 12 is suppressed and accordingly, the connection reliability between the wiring board 11 and the control chip 13 and the connection reliability between the Si-Ph chip 12 and the control chip 13 are Improved.

Modification

A modification of the first embodiment will be described. FIG. 8 is a sectional view illustrating the optical module 1 according to the modification of the first embodiment. FIG. 8 illustrates a state in which the optical module 1 is inserted in the cage 2. The lower wall 3A of the housing 3 is in contact with the lower wall 2A of the cage 2 and the upper wall 3B of the housing 3 is in contact with the upper wall 28 of the cage 2. The heat sink 14 is sandwiched between the lower wall 3A of the housing 3 and the Si-Ph chip 12. The heat sink 14 is in contact with the back surface of the Si-Ph chip 12 and in contact with the lower wall 3A of the housing 3. The heat sink 14 is not disposed between the lower wall 3A of the housing 3 and the wiring board 11. Accordingly, the heat sink 14 is not in contact with the lower surface of the wiring board 11. The heat sink 14 may be in contact with an inner circumferential surface of the through hole 21 of the wiring board 11 or the inner circumferential surface of the through hole 21 of the wiring board 11 and the heat sink 14 may be separated from each other. In the configuration example of the optical module 1 illustrated in FIG. 8, the inner circumferential surface of the through hole 21 of the wiring board 11 and the heat sink 14 are separated from each other.

The thickness of the wiring board 11 may be larger than the thickness of the Si-Ph chip 12 or may be smaller than the thickness of the S-Ph chip 12. In the case where the thickness of the wiring board 11 is larger than the thickness of the Si-Ph chip 12, a part of the heat sink 14 is inserted in the through hole 21 of the wiring board 11. In the case where the thickness of the wiring board 11 is smaller than the thickness of the Si-Ph chip 12, a part of the Si-Ph chip 12 protrudes from the through hole 21 of the wiring board 11. Further, the thickness of the wiring board 11 may be the same as the thickness of the Si-Ph chip 12. In the configuration example of the optical module 1 illustrated in FIG. 8, the thickness of the wiring board 11 is larger than the thickness of the Si-Ph chip 12.

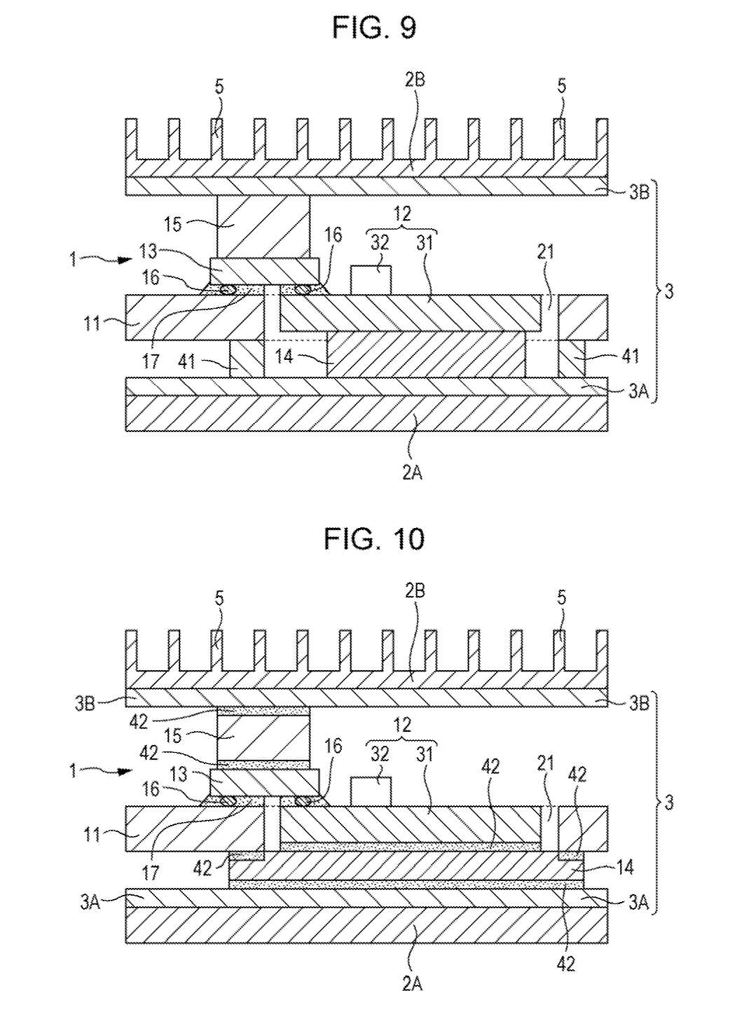

As Illustrated in FIG. 9, a support member 41 may be disposed between the lower wall 3A of the housing 3 and the wiring board 11. FIG. 9 is a sectional view illustrating the optical module 1 according to the modification of the first embodiment. The control chip 13 and the support member 41 may overlap with each other in a plan view seen from a normal direction of the back surface of the control chip 13. The support member 41 may have a frame shape. In the case where the support member 41 has the frame shape, the heat sink 14 is disposed inside the frame-shaped portion of the support member 41. The support member 41 may be formed using a metal material such as copper and aluminum or may be formed using resin having thermal conductivity, for example. The support member 41 is sandwiched between the lower wall 3A of the housing 3 and the wiring board 11, thereby reducing deformation of the wiring board 11 generated when an external force is applied to the optical module 1. As a result, stress applied to the connection portion between the wiring board 11 and the control chip 13 is reduced and thus, the connection reliability between the wiring board 11 and the control chip 13 is improved.

### Second Embodiment

The second embodiment will be described. In the second embodiment, constituent elements same as those of the first embodiment will be denoted by the same reference characters as those of the first embodiment and description thereof will be omitted. FIG. 10 is a sectional view illustrating the optical module 1 according to the second embodiment. FIG. 10 illustrates a state in which the optical module 1 is inserted in the cage 2. Buffer members 42 are provided between the lower wall 3A of the housing 3 and the heat sink 14, between the upper wall 3B of the housing 3 and the heat sink 15, between the wiring board 11 and the heat sink 14, between the Si-Ph chip 12 and the heat sink 14, and between the control chip 13 and the heat sink 15. The optical module 1 according to the second embodiment is not limited to the configuration example of the optical module 1 illustrated in FIG. 10. The buffer member 42 may be provided between the lower wall 3A of the housing 3 and the heat sink 14, between the upper wall 3B of the housing 3 and the heat sink 15, between the wiring board 11 and the heat sink 14, between the Si-Ph chip 12 and the heat sink 14, or between the control chip 13 and the heat sink 15 or any combination thereof.

The buffer member 42 has thermal conductivity. The buffer member 42 may be a sol-like or gel-like fluid material such as thermal grease, for example. The Young's modulus of the fluid material is smaller than the Young's moduli of the heat sinks 14 and 15. By using a fluid material as the buffer member 42, the buffer member 42 absorbs thermal expansion of the heat sinks 14 and 15 or deformation of the heat sinks 14 and 15 generated by external stress or bending moment. As a result, stress applied to the connection portion between the wiring board 11 and the control chip 13 and the connection portion between the Si-Ph chip 12 and the control chip 13 is reduced.

The buffer member 42 may be a sheet-like or tape-like thermal interface material (TIM), Ag paste, solder, or an adhesive having thermal conductivity, for example. By using a thermal interface material, Ag paste, solder, or an adhesive having thermal conductivity as the buffer member 42, it is possible to bond and fix the heat sink 14 on the lower wall 3A of the housing 3, on the wiring board 11, and on the Si-Ph chip 12 and bond and fix the heat sink 15 on the upper wall 3B of the housing 3 and on the control chip 13. In the case where the heat sinks 14 and 15 are bonded and fixed, the Young's modulus of the buffer member 42 is preferably smaller than the Young's moduli of the heat sinks 14 and 15. When the Young's modulus of the buffer member 42 is thus smaller than the Young's moduli of the heat sinks 14 and 15, thermal expansion of the heat sinks 14 and 15 or deformation of the heat sinks 14 and 15 generated by external stress or bending moment is absorbed by the buffer member 42. Accordingly, stress applied to the connection portion between the wiring board 11 and the control chip 13 and the connection portion between the Si-Ph chip 12 and the control chip 13 is reduced.

Modification

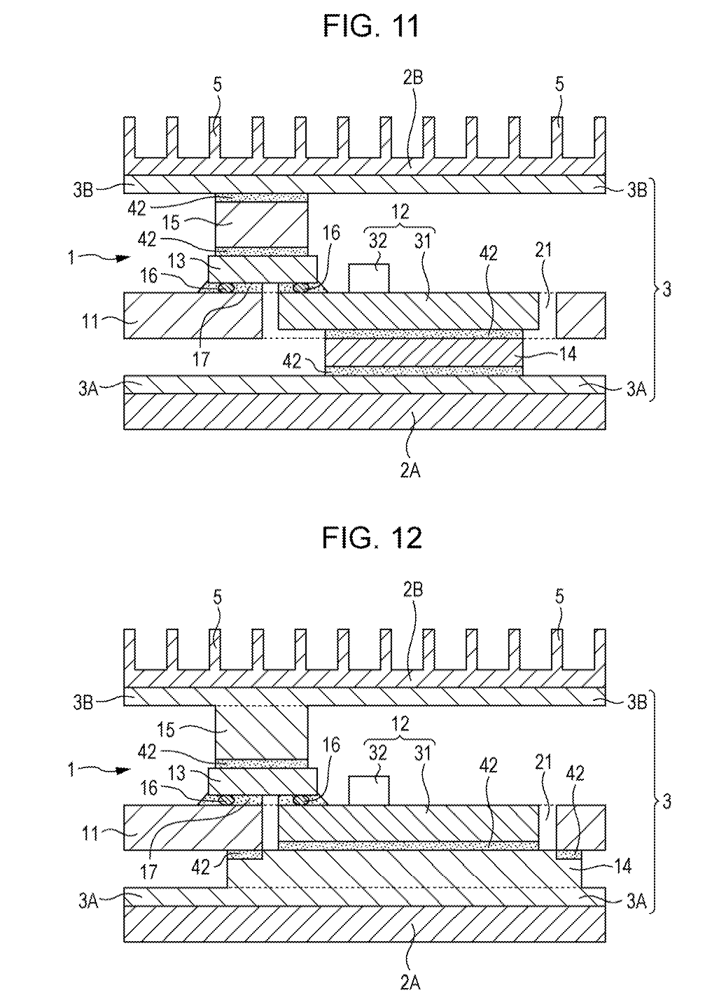

FIG. 11 is a sectional view illustrating the optical module 1 according to a modification of the second embodiment. FIG. 11 illustrates a state in which the optical module 1 is inserted in the cage 2. The buffer members 42 are provided between the lower wall 3A of the housing 3 and the heat sink 14, between the upper wall 38 of the housing 3 and the heat sink 15, between the Si-Ph chip 12 and the heat sink 14, and between the control chip 13 and the heat sink 15. The optical module 1 according to the modification of the second embodiment is not limited to the configuration example of the optical module 1 illustrated in FIG. 11. The buffer member 42 may be provided between the lower wall 3A of the housing 3 and the heat sink 14, between the upper wall 38 of the housing 3 and the heat sink 15, between the Si-Ph chip 12 and the heat sink 14, or between the control chip 13 and the heat sink 15 or any combination thereof.

The thickness of the wiring board 11 may be larger than the thickness of the Si-Ph chip 12 or may be smaller than the thickness of the Si-Ph chip 12. In the configuration example of the optical module 1 illustrated in FIG. 11, the thickness of the wiring board 11 is larger than the thickness of the Si-Ph chip 12. In the case where the thickness of the wiring board 11 is larger than the thickness of the Si-Ph chip 12, the buffer member 42 provided between the Si-Ph chip 12 and the heat sink 14 is disposed inside the through hole 21 of the wiring board 11. In the case where the thickness of the wiring board 11 is larger than the thickness of the Si-Ph chip 12, a part of the heat sink 14 may be inserted in the through hole 21 of the wiring board 11.

In the case where the thickness of the wiring board 11 is smaller than the thickness of the Si-Ph chip 12, a part of the Si-Ph chip 12 protrudes from the through hole 21 of the wiring board 11 and the buffer member 42 provided between the Si-Ph chip 12 and the heat sink 14 is disposed outside the through hole 21 of the wiring board 11. Further, the thickness of the wiring board 11 may be the same as the thickness of the Si-Ph chip 12. In the case where the thickness of the wiring board 11 is the same as the thickness of the Si-Ph chip 12, the buffer member 42 provided between the Si-Ph chip 12 and the heat sink 14 is disposed outside the through hole 21 of the wiring board 11.

### Third Embodiment

The third embodiment will be described. In the third embodiment, constituent elements same as those of the first embodiment and the second embodiment will be denoted by the same reference characters as those of the first embodiment and the second embodiment and description thereof will be omitted. FIG. 12 is a sectional view Illustrating the optical module 1 according to the third embodiment. FIG. 12 illustrates a state in which the optical module 1 is inserted in the cage 2. As illustrated in FIG. 12, the lower wall 3A of the housing 3 and the heat sink 14 are integrated and the upper wall 3B of the housing 3 and the heat sink 15 are integrated. The housing 3 and the heat sinks 14 and 15 are made of a metal material such as copper and aluminum, for example.

The lower wall 3A of the housing 3 and the heat sink 14 are thus integrated, thereby reducing thermal resistance between the lower wall 3A of the housing 3 and the heat sink 14. The upper wall 38 of the housing 3 and the heat sink 15 are thus integrated, thereby reducing thermal resistance between the upper wall 38 of the housing 3 and the heat sink 15. Accordingly, heat radiation performance of the optical module 1 is improved. In addition, the mounting process of the heat sinks 14 and 15 is cut out, being able to reduce the manufacturing cost of the optical module 1. In FIG. 12, the buffer members 42 are provided between the wiring board 11 and the heat sink 14, between the Si-Ph chip 12 and the heat sink 14, and between the control chip 13 and the heat sink 15. The optical module 1 according to the third embodiment is not limited to the configuration example of the optical module 1 illustrated in FIG. 12. The buffer member 42 may be provided between the wiring board 11 and the heat sink 14, between the Si-Ph chip 12 and the heat sink 14, or between the control chip 13 and the heat sink 15 or any combination thereof. Further, the mounting of the buffer member 42 may be omitted.

### Fourth Embodiment

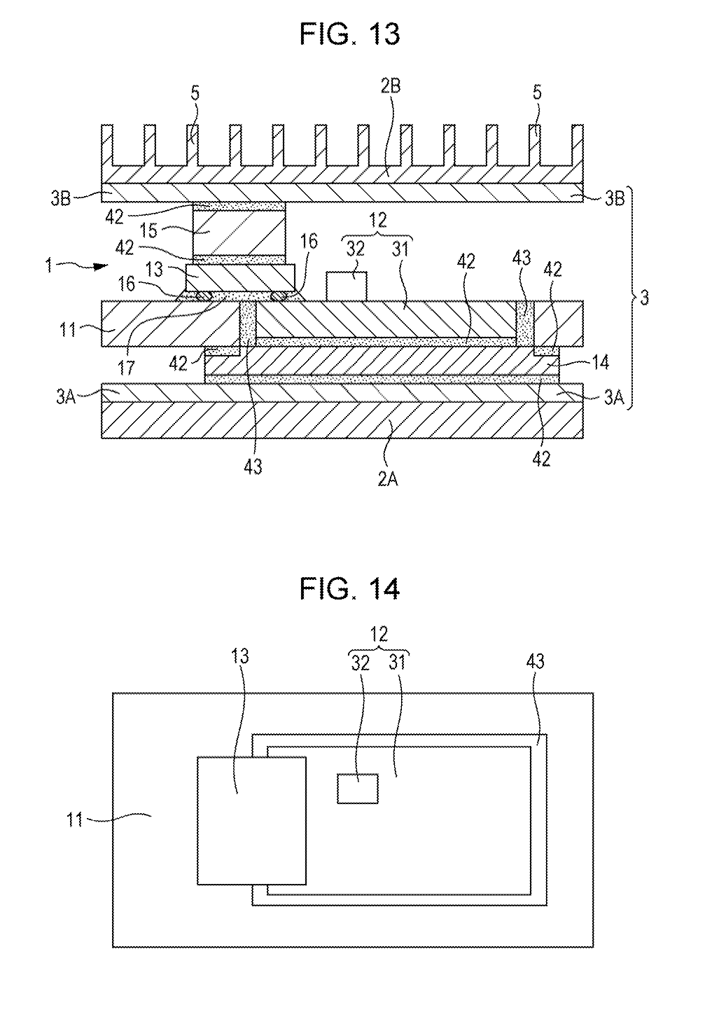

The fourth embodiment will be described. In the fourth embodiment, constituent elements same as those of the first embodiment to the third embodiment will be denoted by the same reference characters as those of the first embodiment to the third embodiment and description thereof will be omitted. FIG. 13 is a sectional view illustrating the optical module 1 according to the fourth embodiment. FIG. 13 illustrates a state in which the optical module 1 is inserted in the cage 2. FIG. 14 is a plan view illustrating the optical module 1 according to the fourth embodiment. In FIG. 14, Illustration of the housing 3, the heat sink 15, and the buffer member 42 is omitted. As illustrated in FIGS. 13 and 14, an adhesive 43 is provided between the wiring board 11 and the Si-Ph chip 12. Therefore, the Si-Ph chip 12 and the adhesive 43 are disposed inside the through hole 21 of the wiring board 11. An outer circumference of the Si-Ph chip 12 is reinforced by the adhesive 43. The optical module 1 according to the fourth embodiment is not limited to the configuration example of the optical module 1 illustrated in FIG. 13. The buffer member 42 may be provided between the lower wall 3A of the housing 3 and the heat sink 14, between the upper wall 3B of the housing 3 and the heat sink 15, between the wiring board 11 and the heat sink 14, between the Si-Ph chip 12 and the heat sink 14, or between the control chip 13 and the heat sink 15 or any combination thereof. Further, the mounting of the buffer member 42 may be omitted.

The Young's modulus of the adhesive 43 is preferably smaller than the Young's moduli of the wiring board 11, the Si-Ph chip 12, and the heat sink 14. In the case where the Young's modulus of the adhesive 43 is smaller than the Young's moduli of the wiring board 11 and the Si-Ph chip 12, the adhesive 43 is preferentially deformed by an external force or thermal stress and stress applied to the wiring board 11 and the Si-Ph chip 12 is reduced. In the case where the Young's modulus of the adhesive 43 is smaller than the Young's moduli of the wiring board 11, the Si-Ph chip 12, and the heat sink 14, the adhesive 43 is preferentially deformed by external force or thermal stress and stress applied to the wiring board 11, the Si-Ph chip 12, and the heat sink 14 is reduced. The adhesive 43 covers a part or the whole of the lateral surfaces of the Si-Ph chip 12. In FIG. 14, the adhesive 43 covers the whole lateral surfaces of the Si-Ph chip 12.

### Fifth Embodiment

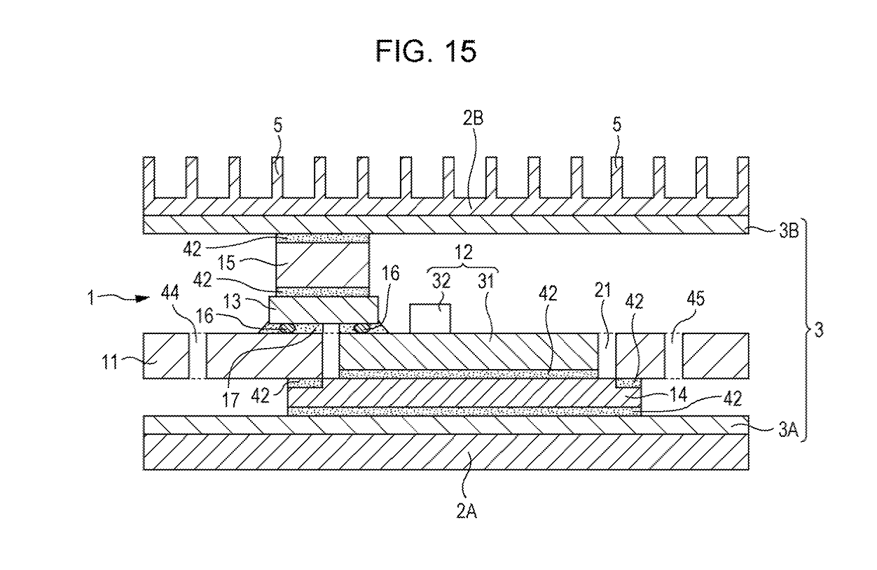

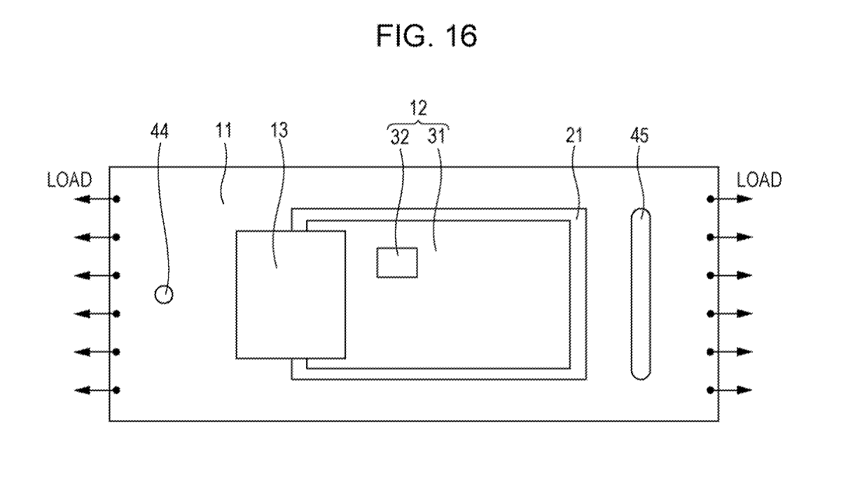

The fifth embodiment will be described. In the fifth embodiment, constituent elements same as those of the first embodiment to the fourth embodiment will be denoted by the same reference characters as those of the first embodiment to the fourth embodiment and description thereof will be omitted. FIG. 15 is a sectional view Illustrating the optical module 1 according to the fifth embodiment. FIG. 15 illustrates a state in which the optical module 1 is inserted in the cage 2. FIG. 16 is a plan view illustrating the optical module 1 according to the fifth embodiment. In FIG. 16, illustration of the housing 3, the heat sink 15, and the buffer member 42 is omitted. A hole 44 and a slit 45 are provided in the wiring board 11. The Si-Ph chip 12, the control chip 13, and the through hole 21 are disposed in the central portion of the wiring board 11 and the hole 44 and the slit 45 are disposed on end portions or near the end portions of the wiring board 11. The hole 44 and the slit 45 are separated from the Si-Ph chip 12 and the control chip 13.

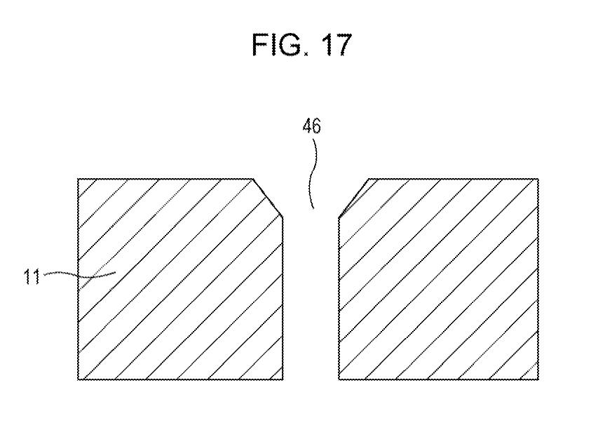

As illustrated in FIG. 17, a counterbore 46 may be provided in the wiring board 11. FIG. 17 is a sectional view illustrating the wiring board 11. The hole 44, the slit 45, or the counterbore 46 or any combination thereof may be provided in the wiring board 11. The hole 44, the slit 45, and the counterbore 46 may penetrate through the wiring board 11. The hole 44, the slit 45, and the counterbore 46 may terminate inside the wiring board 11 without penetrating through the wiring board 11. A plurality of holes 44, a plurality of slits 45, and a plurality of counterbores 46 may be provided in the wiring board 11. In the case where a load is applied to the end portions of the wiring board 11, portions of the wiring board 11 around the hole 44, the slit 45, and the counterbore 46 preferentially deform, so that deformation of a portion of the wiring board 11 around the through hole 21 is reduced. Accordingly, stress applied to the connection portion between the wiring board 11 and the control chip 13 is reduced and thus, the connection reliability between the wiring board 11 and the control chip 13 is improved. The hole 44, the slit 45, and the counterbore 46 are an example of a groove. The optical module 1 according to the fifth embodiment is not limited to the configuration example of the optical module 1 illustrated in FIGS. 15 and 16 and the disposition of the buffer member 42 may be omitted. Further, as is the case with the fourth embodiment, the adhesive 43 may be provided between the wiring board 11 and the Si-Ph chip 12.

### Sixth Embodiment

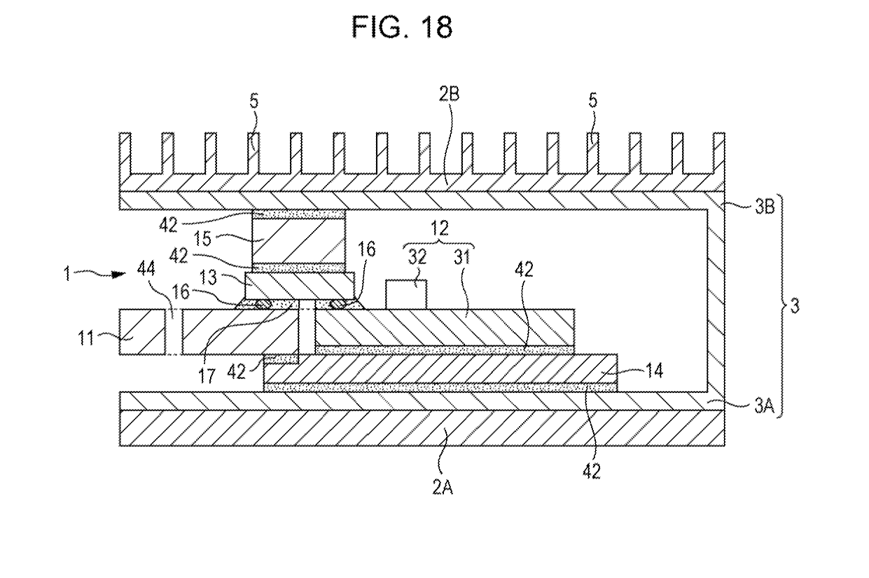

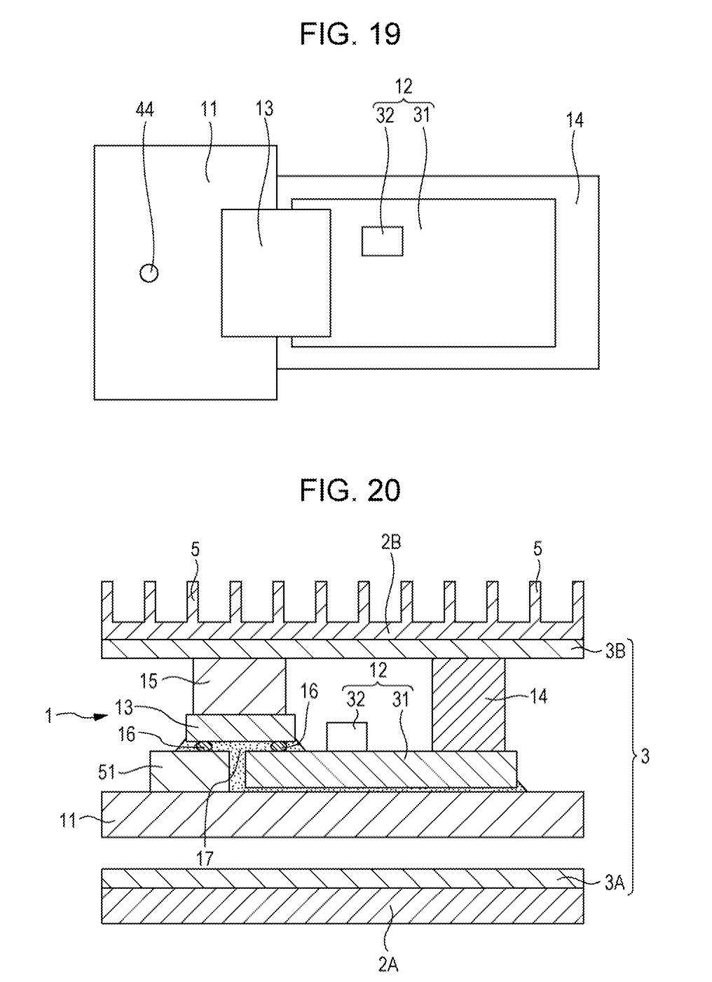

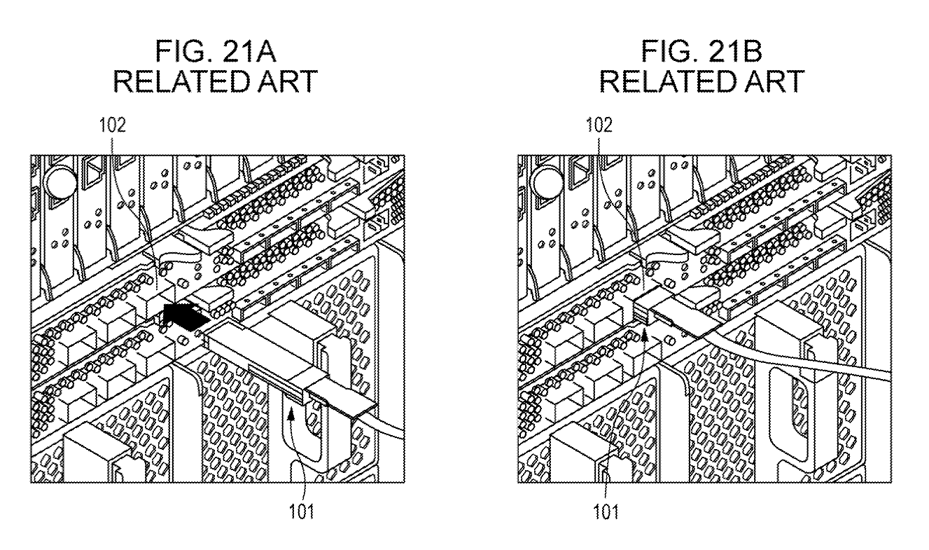

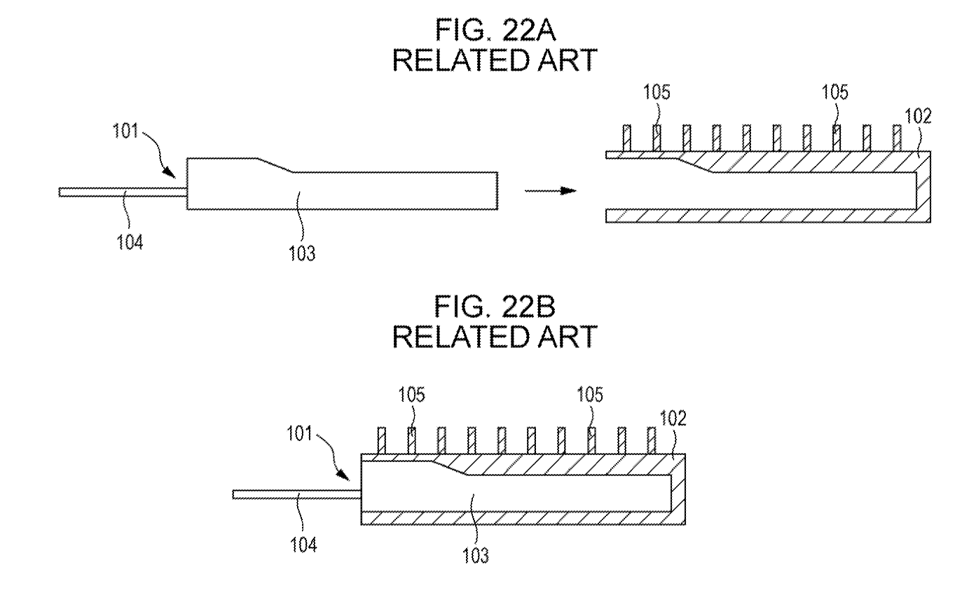

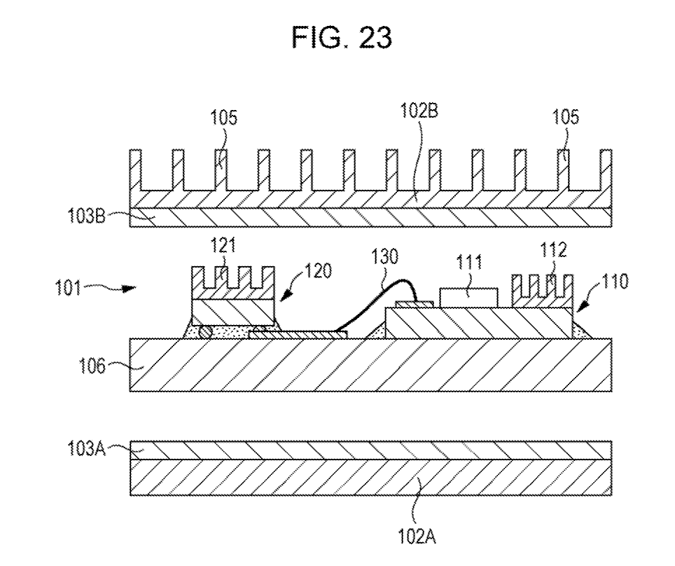

The sixth embodiment will be described. In the sixth embodiment, constituent elements same as those of the first embodiment to the fifth embodiment will be denoted by the same reference characters as those of the first embodiment to the fifth embodiment and description thereof will be omitted. FIG. 18 is a sectional view illustrating the optical module 1 according to the sixth embodiment. FIG. 18 illustrates a state in which the optical module 1 is inserted in the cage 2. FIG. 19 is a plan view illustrating the optical module 1 according to the sixth embodiment. In FIG. 19, illustration of the housing 3, the heat sink 15, and the buffer member 42 is omitted. As illustrated in FIGS. 18 and 19, the through hole 21 is not provided in the wiring board 11 and the Si-Ph chip 12 is disposed adjacent to the end portion of the wiring board 11. The control chip 13 is disposed in a manner to straddle the wiring board 11 and the Si-Ph chip 12. Though the wiring board 11 has the hole 44 in FIGS. 18 and 19, the wiring board 11 may have the slit 45 or the counterbore 46 instead of the hole 44 or the wiring board 11 may have the hole 44, the slit 45, or the counterbore 46 or any combination thereof. Further, as is the case with the fourth embodiment, the adhesive 43 may be provided between the wiring board 11 and the Si-Ph chip 12.

The embodiments may be implemented in combination as much as possible. In the optical module 1 according to each embodiment, heat radiation of the laser diode 32 of the Si-Ph chip 12 is performed via the heat sink 14 and the lower wall 3A of the housing 3 and heat radiation of the circuit of the control chip 13 is performed via the heat sink 15 and the upper wall 3B of the housing 3. Thus, it is possible to guide the heat of the Si-Ph chip 12 to the lower wall 3A of the housing 3 and guide the heat of the control chip 13 to the upper wall 3B of the housing 3, being able to realize efficient heat radiation of the optical module 1.

FIG. 20 is a sectional view illustrating the optical module 1 according to a reference example. FIG. 20 illustrates a state in which the optical module 1 is inserted in the cage 2. The control chip 13 is placed on the Si-Ph chip 12 and a spacer 51. The heat sink 14 is sandwiched between the upper wall 3B of the housing 3 and the Si-Ph chip 12. The heat sink 14 is in contact with the circuit surface of the Si-Ph chip 12 and in contact with the upper wall 3B of the housing 3. In FIG. 20, heat radiation of the laser diode 32 of the Si-Ph chip 12 is performed via the heat sink 14 and the upper wall 3B of the housing 3 and heat radiation of the circuit of the control chip 13 is performed via the heat sink 15 and the upper wall 3B of the housing 3. In the case of guiding the heat of the Si-Ph chip 12 and the heat of the control chip 13 to the upper wall 3B of the housing 3, the heat is concentrated on the upper wall 3B of the housing 3, so that heat transfer of the Si-Ph chip 12 and the control chip 13 is degraded.

In the optical module 1 according to each embodiment, the heat of the S-Ph chip 12 is guided to the lower wall 3A of the housing 3 and the heat of the control chip 13 is guided to the upper wall 38 of the housing 3. Thus, heat transfer of the Si-Ph chip 12 and the control chip 13 is improved. In the optical module 1 according to each embodiment, since the heat sink 14 is thinner than that of the optical module 1 according to the reference example of FIG. 20, the thermal expansion amount of the heat sink 14 is smaller. Therefore, in the optical module 1 according to each embodiment, stress which is generated by thermal expansion of the heat sink 14 and applied to the wiring board 11 or the Si-Ph chip 12 is reduced. Accordingly, the connection reliability between the wiring board 11 and the control chip 13 and the connection reliability between the Si-Ph chip 12 and the control chip 13 are Improved.

In the optical module 1 according to each embodiment, the circuit surface of the Si-Ph chip 12 and the circuit surface of the control chip 13 face each other and the Si-Ph chip 12 and the control chip 13 are electrically connected via the bumps 16. Thus, the distance between the Si-Ph chip 12 and the control chip 13 is reduced and the communication speed between the Si-Ph chip 12 and the control chip 13 is improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An optical module comprising:
a housing;
a substrate configured to have a through hole;
a first chip configured to have a first heating member and be disposed inside the through hole;
a second chip configured to have a second heating member, the second chip being placed on the substrate and the first chip with a bump interposed;
a first heat conduction member configured to be sandwiched between a lower wall of the housing and the first chip and transfer heat generated by the first heating member to the lower wall of the housing; and
a second heat conduction member configured to be sandwiched between an upper wall of the housing and the second chip and transfer heat generated by the second heating member to the upper wall of the housing.

2. The optical module according to claim 1, wherein
the first heat conduction member covers a part or a whole of an opening of the through hole, and
a part of the first heat conduction member is sandwiched between the lower wall of the housing and the substrate.

3. The optical module according to claim 1, wherein a part of the first heat conduction member is inserted in the through hole.

4. The optical module according to claim 2, wherein
a recess is provided in a central portion of the first heat conduction member,
a part of the first chip is accommodated in the recess, and
an outer peripheral portion of the first heat conduction member is sandwiched between the lower wall of the housing and the substrate.

5. The optical module according to claim 1, further comprising:
a buffer member configured to be provided between the first chip and the first heat conduction member, between the first heat conduction member and the lower wall of the housing, between the second chip and the second heat conduction member, or between the second heat conduction member and the upper wall of the housing or any combination thereof, wherein
a Young's modulus of the buffer member is lower than Young's modulli of the first heat conduction member and the second heat conduction member.

6. The optical module according to claim 2, further comprising:
a buffer member configured to be provided between the substrate and the first heat conduction member, between the first chip and the first heat conduction member, between the first heat conduction member and the lower wall of the housing, between the second chip and the second heat conduction member, or between the second heat conduction member and the upper wall of the housing or any combination thereof, wherein
a Young's modulus of the buffer member is lower than Young's modulli of the first heat conduction member and the second heat conduction member.

7. The optical module according to claim 1, wherein
the first heat conduction member and the lower wall of the housing are Integrated, and
the second heat conduction member and the upper wall of the housing are integrated.

8. The optical module according to claim 7, further comprising:
a buffer member configured to be provided between the first chip and the first heat conduction member or between the second chip and the second heat conduction member or a combination thereof, wherein
a Young's modulus of the buffer member is lower than Young's moduli of the first heat conduction member and the second heat conduction member.

9. The optical module according to claim 1, further comprising:
an adhesive configured to be provided between the substrate and the first chip, wherein
a Young's modulus of the adhesive is lower than Young's moduli of the substrate and the first chip.

10. The optical module according to claim 1, wherein a groove is provided in the substrate.

11. The optical module according to claim 1, wherein the first heating member is a laser diode.

12. The optical module according to claim 11, wherein the second heating member is a control chip for the laser diode.

13. An optical module comprising:
a housing;
a substrate;
a first chip configured to have a first heating member and be disposed adjacent to the substrate;
a second chip configured to have a second heating member, the second chip being placed on the substrate and the first chip with a bump interposed;
a first heat conduction member configured to be sandwiched between a lower wall of the housing and the first chip and transfer heat generated by the first heating member to the lower wall of the housing; and
a second heat conduction member configured to be sandwiched between an upper wall of the housing and the second chip and transfer heat generated by the second heating member to the upper wall of the housing.
